(19) United States
(12) Patent Application Publication
(10) Pub. No.: US 2023/0336194 A1
(43) Pub. Date: Oct. 19, 2023

(54) MULTI-FREQUENCY SAMPLING SYSTEM

(71) Applicant: BAE SYSTEMS Information and Electronic Systems Integration Inc., Nashua, NH (US)

(72) Inventors: William H. Cantrell, Aubrey, TX (US); Mark Tinch, Rhome, TX (US); Mark E. Hughes, Flower Mound, TX (US); Allan K. Redenbaugh, Frisco, TX (US)

(73) Assignee: BAE SYSTEMS Information and Electronic Systems Integration Inc., Nashua, NH (US)

(21) Appl. No.: 17/659,554

(22) Filed: Apr. 18, 2022

(51) Int. Cl. H04B 1/00; H04B 1/58

(52) U.S. Cl. CPC H04B 1/0078; H04B 1/588; H04B 1/0042

(57) ABSTRACT

Techniques are provided for a multi-frequency sampling system. A system implementing the techniques according to an embodiment includes a first bandpass filter to filter a radio frequency (RF) signal to generate a first filtered signal in a first frequency band, and a second bandpass filter to filter the RF signal to generate a second filtered signal in a second frequency band. The system also includes a first analog to digital converter (ADC) operating at a first sampling frequency to convert the first filtered signal to a first digital signal and a second ADC operating at a second sampling frequency to convert the second filtered signal to a second digital signal. The first frequency band is selected to avoid a first Nyquist boundary zone associated with the first sampling frequency and the second frequency band is selected to avoid a second Nyquist boundary zone associated with the second sampling frequency.

### FIELD OF DISCLOSURE

The present disclosure relates to digital receivers, and more particularly to the use of multiple sampling frequencies to avoid Nyquist foldover zone boundaries.

### BACKGROUND

Many signal processing applications, including communications, radar systems, and electronic warfare applications, operate on received radio frequency (RF) signals to process embedded signals of interest. As the upper frequency range of these RF signals increases, it becomes more difficult to convert the RF analog signal into the digital domain without using a heterodyne approach (e.g., mixing the RF signal down to an intermediate frequency (IF) signal prior to sampling). The heterodyne approach, however, is generally associated with one or more of increased cost, size, weight, and power, which may be unsuitable for some applications where those factors are tightly constrained.

### BRIEF DESCRIPTION OF THE DRAWINGS

FIG. 1 is a high level block diagram of a receiver employing a multi-frequency sampling system, in accordance with certain embodiments of the present disclosure.

FIG. 2 is a block diagram of the multi-frequency sampling system of FIG. 1, configured in accordance with certain embodiments of the present disclosure.

FIG. 3 illustrates frequency spectra associated with the multi-frequency sampling system of FIG. 1, configured in accordance with certain embodiments of the present disclosure.

FIG. 4 is a block diagram of a multi-channel implementation of the multi-frequency sampling system of FIG. 1, configured in accordance with certain embodiments of the present disclosure.

FIG. 5 is a block diagram of a parallel implementation of the multi-frequency sampling system of FIG. 1, configured in accordance with certain embodiments of the present disclosure.

FIG. 6 is a flowchart illustrating a methodology for multi-frequency sampling, in accordance with an embodiment of the present disclosure.

Although the following Detailed Description will proceed with reference being made to illustrative embodiments, many alternatives, modifications, and variations thereof will be apparent in light of this disclosure.

### DETAILED DESCRIPTION

Techniques are provided herein for multi-frequency sampling to avoid Nyquist foldover zone boundaries, allowing for direct conversion of analog RF signals to the digital domain. As noted previously, a heterodyne receiver approach is often employed to convert higher frequency analog RF signals into the digital domain due to the difficulties imposed by direct conversion. The heterodyne approach, however, is generally associated with increased cost, size, weight, and power, which may be unsuitable for some applications where those factors are tightly constrained.

To this end, and in accordance with an embodiment of the present disclosure, a multi-frequency sampling system is disclosed which provides for direct conversion of analog RF signals without the requirement for first mixing the RF signal to an IF signal. The disclosed system employs two or more analog to digital converters (ADCs) which each operate at different sampling rates and are therefore associated with different Nyquist frequencies and Nyquist boundary zones. Any one of the ADCs can be selected for use (along with an appropriate bandpass filter) depending on the frequency band that a given signal of interest occupies, as will be explained in greater detail below.

The disclosed multi-frequency sampling system can be used, for instance, with receivers in a wide variety of applications including, for example, radar systems and communication systems that can be deployed on aircraft (manned and unmanned), guided munitions and projectiles, space-based systems, electronic warfare systems, and other communication systems including cellular telephones, and smartphones, although other applications will be apparent. In accordance with an embodiment, the multi-frequency sampling system includes a first bandpass filter configured to filter a radio frequency (RF) signal to generate a first filtered signal in a first frequency band. The system also includes a second bandpass filter configured to filter the RF signal to generate a second filtered signal in a second frequency band. The system further includes a first analog to digital converter (ADC) operating at a first sampling frequency and configured to convert the first filtered signal to a first digital signal. The system further includes a second ADC operating at a second sampling frequency and configured to convert the second filtered signal to a second digital signal. The first frequency band is selected to avoid a first Nyquist boundary zone associated with the first sampling frequency and the second frequency band is selected to avoid a second Nyquist boundary zone associated with the second sampling frequency.

It will be appreciated that the techniques described herein may provide improved receiver performance, in terms of cost, size, weight, and/or power consumption, compared to systems that use a heterodyne approach. Numerous embodiments and applications will be apparent in light of this disclosure.

System Architecture

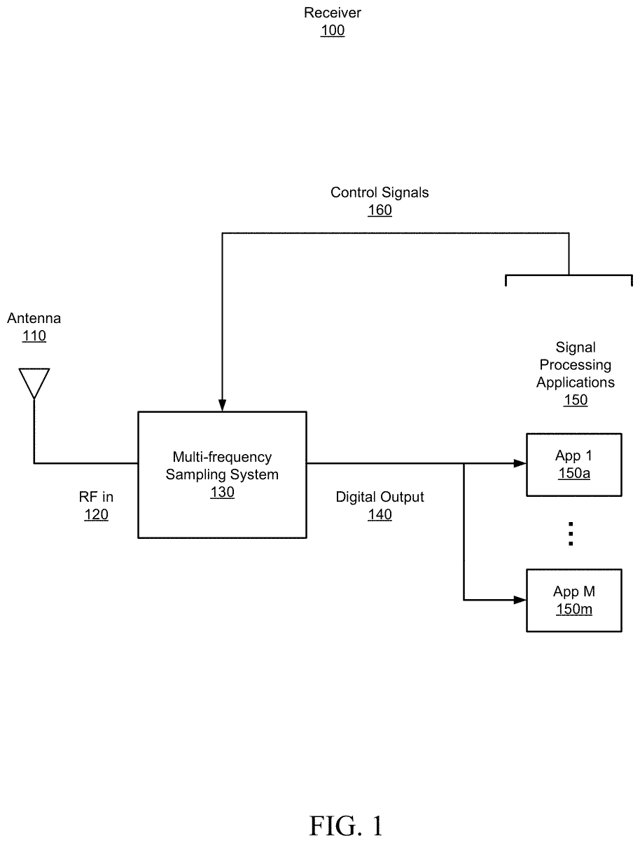

FIG. 1 is a high level block diagram of a receiver 100 employing a multi-frequency sampling system, in accordance with certain embodiments of the present disclosure. The receiver is shown to include an antenna 110, the multi-frequency sampling system 130, signal processing applications 150. The antenna 110 is configured to provide a received RF signal (RF in) 120 to the multi-frequency sampling system 130. In certain applications the RF signal can be filtered and/or amplified.

The multi-frequency sampling system 130 is configured to convert the received RF signal 120 directly from the analog domain to the digital domain by switching between multiple bandpass filters and ADCs operating at different sampling frequencies, as will be explained below. In some embodiments, the switching and filtering may be controlled by signals 160 that are generated external to the multi-frequency sampling system 130.

In some embodiments, the digital output 140 of the multi-frequency sampling system 130 may be provided to one or more downstream signal processing applications 150a through 150m. These applications may be configured to process different signals of interest that are embedded (e.g., occupy different frequency bands) within the received RF signal. The applications may also generate the control signals 160 such that they receive the desired digitized signals 140.

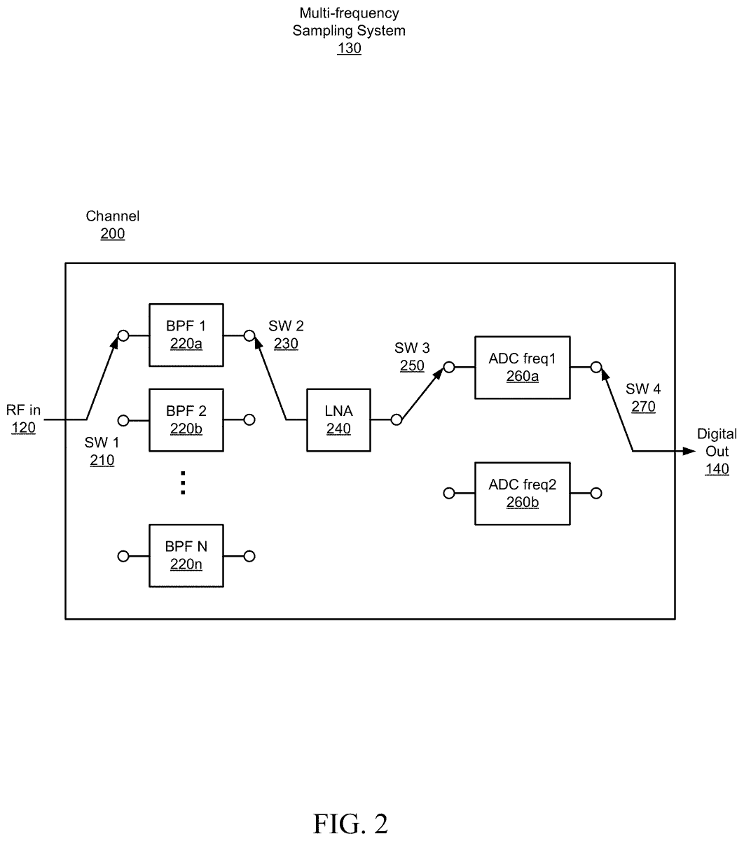

FIG. 2 is a block diagram of the multi-frequency sampling system 130 of FIG. 1, configured in accordance with certain embodiments of the present disclosure. One channel 200 of the multi-frequency sampling system 130 is shown to include an input switch (SW 1) 210, bandpass filters 220 (also referred to as pre-selector filters), a filter output switch (SW 2) 230, a low noise amplifier (LNA) 240, an ADC input switch (SW 3) 250, two ADCs 260 configured to operate at different sampling rates or sampling frequencies, and an output switch (SW 4) 270.

The input switch 210 is configured to selectively switch the RF input signal 120 to any of the bandpass filters 220a, . . . 220n. In some embodiments, the input switch 210 may be controlled by control signals 160 provided by downstream applications or consumers of the digitized signals. Each of the bandpass filters 220 is configured to filter the RF input signal to a different frequency range. Any number of bandpass filters may be implemented depending on the number of signal frequency bands that are of interest. So, for example, at a given time, a downstream application may need to process a signal of interest in a particular frequency band and therefore control switch 210 to route the RF input 120 the appropriate bandpass filter 220.

The filter output switch 230 is configured to route the output of the selected bandpass filter to the next component (e.g., LNA 240). In some embodiments, the position of switch 230 may be linked to, or synchronized with, the selected position of switch 210.

The LNA 240 is configured to amplify the output of the bandpass filtered signal prior to sampling.

The ADC input switch 250 is configured to selectively couple the output of the LNA 240 to one of the ADCs, 260a or 260b. In some embodiments, the position of switch 250 may be determined by the position of switch 210 such that a pre-determined group of bandpass filters is associated with ADC 260a and the remaining bandpass filters are associated with ADC 260b. In some embodiments, more than two ADCs may be employed depending on the frequency bands of interest and the ADC sampling rates that can be achieved in a practical manner, as will be explained below.

The ADCs 260 are configured to sample or digitize the filtered and amplified signals. ADC 260a operates at a first sampling rate (freq 1), and ADC 260b operates at a second sampling rate (freq 2).

The output switch 270 is configured to route the output of the selected ADC filter, 260a or 260b, to be provided as digital output signal 140 of this channel of the multi-frequency sampling system 130. In some embodiments, the position of switch 270 may be linked to, or synchronized with, the selected position of switch 250.

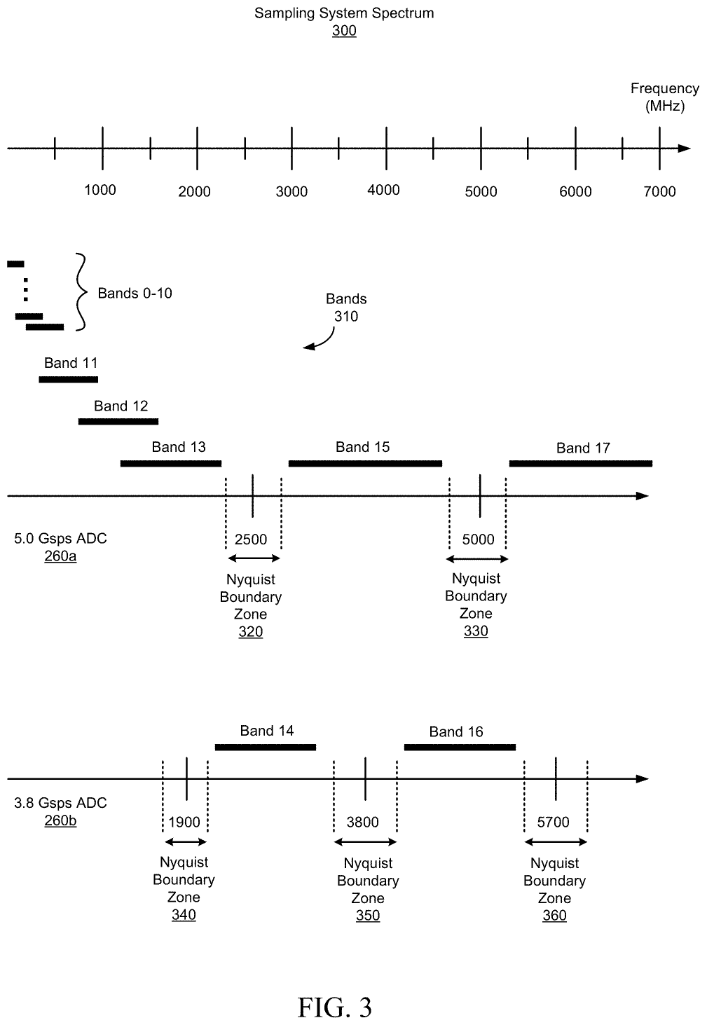

FIG. 3 illustrates frequency spectra 300 associated with the multi-frequency sampling system of FIG. 1, configured in accordance with certain embodiments of the present disclosure. In this example, the frequency spectrum extends up to 7000 MHz (e.g., 7 GHz). There are 18 frequency bands of interest 310 shown in this example (bands 0 through 17). Each of the bandpass filters 220 of FIG. 2 is configured to filter the input RF signal to one of the 18 frequency bands. Each frequency band extends from a low end frequency f_lo to a high end frequency f_hi. In some embodiments, the frequency bands may extend over a sub-octave frequency range (e.g., such that f_hi/f_lo<2) and each band may partially overlap with adjacent bands.

Also, in this example, the first ADC 260a is configured to sample at a sampling rate of 5 Giga-samples per second (Gsps), and the second ADC 260b is configured to sample at a sampling rate of 3.8 Gsps. The Nyquist foldover frequency occurs at integer multiples of one half of the sampling frequency. So, for ADC 260a, the foldover frequencies are at 2500 MHz, 5000 MHz, and 7500 MHz, etc. Similarly, for ADC 260b, the foldover frequencies are at 1900 MHz, 3800 MHz, and 5700 MHz, etc. Thus, for ADC 260a, sampling at 5 Gsps, the first Nyquist boundary zone 320 is centered at 2500 MHz and extends downward in frequency by the width of the guard band of the bandpass filter for band 13 and extends upward in frequency by the guard band of the bandpass filter for band 15. Any signals that occupy zone 320, for example signals in band 14, cannot be properly sampled by ADC 260a without corruption due to aliasing effects. Also, for ADC 260a, the second Nyquist boundary zone 330 is centered at 5000 MHz and extends downward in frequency by the width of the guard band of the bandpass filter for band 15 and extends upward in frequency by the guard band of the bandpass filter for band 17. Thus, ADC 260a should not be used to sample signals in band 16 which overlaps zone 330.

Similarly, for ADC 260b, sampling at 3.8 Gsps, the first Nyquist boundary zone 340 is centered at 1900 MHz and extends downward in frequency by the width of the guard band of the bandpass filter for band 12 and extends upward in frequency by the guard band of the bandpass filter for band 14. Any signals that occupy zone 340, for example signals in band 13, cannot be properly sampled by ADC 260b without corruption due to aliasing effects. Likewise, for ADC 260b, the second Nyquist boundary zone 350 is centered at 3800 MHz and extends downward in frequency by the width of the guard band of the bandpass filter for band 14 and extends upward in frequency by the guard band of the bandpass filter for band 16. Thus, ADC 260b should not be used to sample signals in band 15 which overlaps zone 350. Continuing with ADC 260b, the third Nyquist boundary zone 360 is centered at 5700 MHz and extends downward in frequency by the width of the guard band of the bandpass filter for band 16, and therefore should not be used to sample signals in band 17 which overlaps zone 360. ADC 260b, sampling at 3.8 Gsps, can however be used to obtain coverage for bands 14 and 16 because the Nyquist boundary zones 340, 350, 360 for this ADC occur outside of bands 14 and 16.

Thus, by controlling the switches (e.g., switch 210), the multi-frequency sampling system 130 can be dynamically configured to use the first ADC 260a for bands 1-13, 15, and 17, and to use the second ADC 260b for bands 14 and 16.

In general, the number of ADCs and the sampling rates of the ADCs are selected so that at least one ADC is available for each frequency band of interest to avoid placing a Nyquist boundary zone within that frequency band of interest.

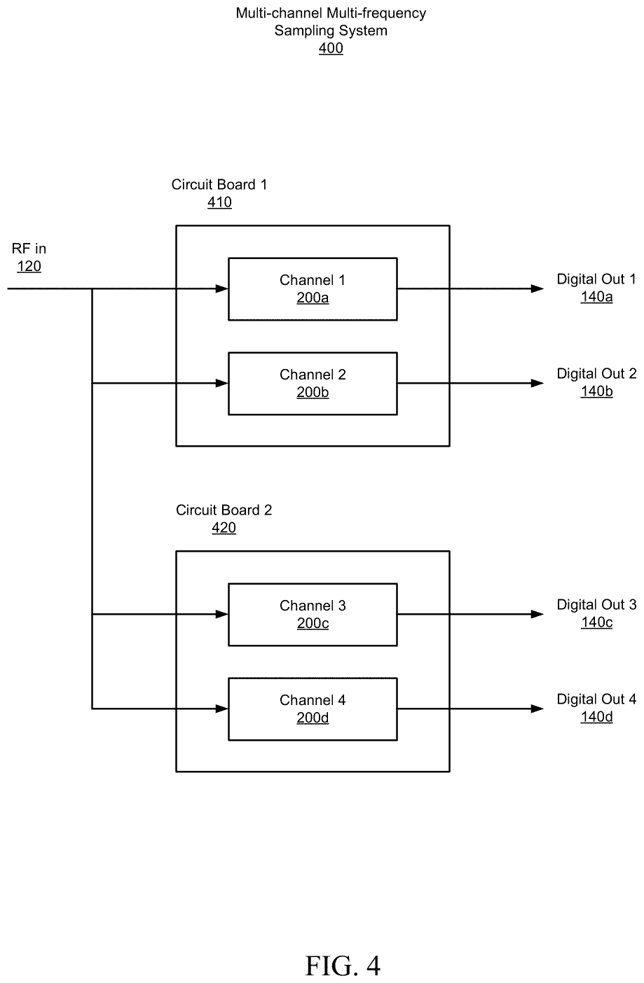

FIG. 4 is a block diagram of a multi-channel implementation 400 of the multi-frequency sampling system 130 of FIG. 1, configured in accordance with certain embodiments of the present disclosure. The multi-channel implementation 400 of this example is shown to include four channels 200a, . . . 200d, each channel providing a digital output 140a, . . . 140d which can be associated with a different frequency band of interest through selective control of the switches of that channel. In some embodiments, the first two channels 200a, 200b may be deployed on a first circuit board 410 and the second two channels 200c, 200d may be deployed on a second circuit board 420. In some embodiments the circuit boards may be implemented as VPX circuit boards configured to conform to a 3U VPX form factor (e.g., a VME-based PCI-extended 3 rack unit).

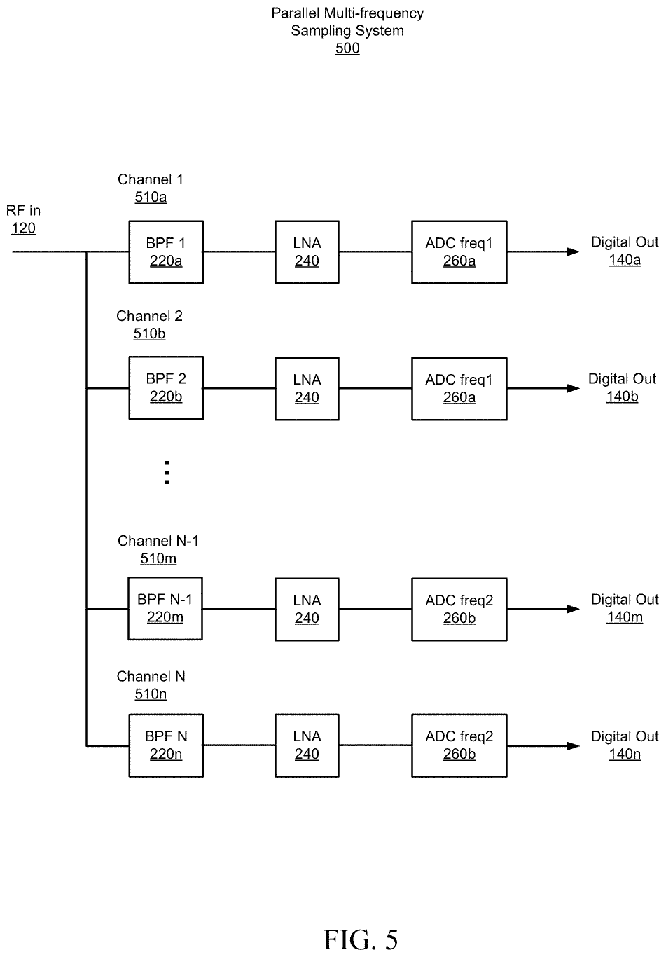

FIG. 5 is a block diagram of a parallel implementation 500 of the multi-frequency sampling system 130 of FIG. 1, configured in accordance with certain embodiments of the present disclosure. In this example, rather than using a switch to select a combination of bandpass filter and ADC, as previously described, each channel 510 comprises a bandpass filter and associated ADC to provide parallel operation so that separate digital outputs 140a, . . . 140n can be generated in parallel, one for each frequency band of interest. For example, the first channel 510a comprises a first bandpass filter 220a to cover the first frequency band of interest and an ADC 260a operating at the first sampling frequency that is compatible with the first frequency band. Similarly, down the line, the n-th channel 510n comprises an n-th bandpass filter 220n to cover the n-th frequency band of interest and an ADC 260b operating at the second sampling frequency that is compatible with the n-th frequency band.

Methodology

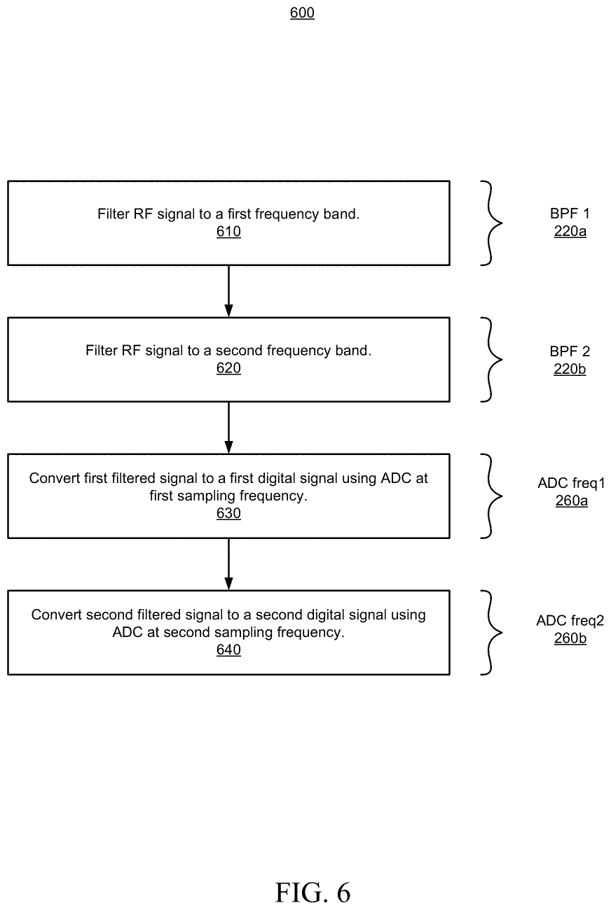

FIG. 6 is a flowchart illustrating a methodology 600 for multi-frequency sampling, in accordance with an embodiment of the present disclosure. As can be seen, example method 600 includes a number of phases and sub-processes, the sequence of which may vary from one embodiment to another. However, when considered in aggregate, these phases and sub-processes form a process for multi-frequency sampling to avoid Nyquist foldover zone boundaries, in accordance with certain of the embodiments disclosed herein, for example as illustrated in FIGS. 1-5, as described above. However other system architectures can be used in other embodiments, as will be apparent in light of this disclosure. To this end, the correlation of the various functions shown in FIG. 6 to the specific components illustrated in the figures, is not intended to imply any structural and/or use limitations. Rather other embodiments may include, for example, varying degrees of integration wherein multiple functionalities are effectively performed by one system. Numerous variations and alternative configurations will be apparent in light of this disclosure.

In one embodiment, method 600 commences, at operation 610, by filtering a received RF signal to generate a first filtered signal in a first frequency band. At operation 620, the received RF signal is filtered to generate a second filtered signal in a second frequency band. In some embodiments, bandpass filters are employed to perform the filtering operations.

At operation 630, the first filtered signal is converted to a first digital signal by a first ADC operating at a first sampling frequency. At operation 640, the second filtered signal is converted to a second digital signal by a second ADC operating at a second sampling frequency.

The first frequency band is selected to avoid a first Nyquist boundary zone associated with the first sampling frequency and the second frequency band is selected to avoid a second Nyquist boundary zone associated with the second sampling frequency, as previously described.

Of course, in some embodiments, additional operations may be performed, as previously described in connection with the system. For example, the received RF may be filtered to additional frequency bands of interest which are then converted to additional digital signals by the first or the second ADC.

In some embodiments, the first sampling frequency is in the range of 3790 MHz to 3810 MHz and the second sampling frequency is in the range of 4990 MHz to 5010 MHz. In some embodiments, the first frequency band and the second frequency band each extend over a sub-octave frequency range and the first frequency band partially overlaps the second frequency band.

In some embodiments, the first Nyquist boundary zone includes: a first sub-zone centered at one half of the first sampling frequency and extending over a guard band range of the first bandpass filter; and a second sub-zone centered at the first sampling frequency and extending over the guard band range of the first bandpass filter. In some embodiments, the second Nyquist boundary zone includes: a first sub-zone centered at one half of the second sampling frequency and extending over a guard band range of the second bandpass filter; and a second sub-zone centered at the second sampling frequency and extending over the guard band range of the second bandpass filter.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still cooperate or interact with each other.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system. The embodiments are not limited in this context.

The terms “circuit” or “circuitry,” as used in any embodiment herein, are functional structures that include hardware, or a combination of hardware and software, and may comprise, for example, singly or in any combination, hardwired circuitry, programmable circuitry such as computer processors comprising one or more individual instruction processing cores, state machine circuitry, and/or gate level logic. The circuitry may include a processor and/or controller programmed or otherwise configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), communications system, radar system, desktop computers, laptop computers, tablet computers, servers, smartphones, etc. Other embodiments may be implemented as software executed by a programmable device. In any such hardware cases that include executable software, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Numerous specific details have been set forth herein to provide a thorough understanding of the embodiments. It will be understood, however, that other embodiments may be practiced without these specific details, or otherwise with a different set of details. It will be further appreciated that the specific structural and functional details disclosed herein are representative of example embodiments and are not necessarily intended to limit the scope of the present disclosure. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

### Further Example Embodiments

The following examples pertain to further embodiments, from which numerous permutations and configurations will be apparent.

One example embodiment of the present disclosure provides a sampling system comprising: a first bandpass filter configured to filter a received radio frequency (RF) signal to generate a first filtered signal in a first frequency band; a second bandpass filter configured to filter the received RF signal to generate a second filtered signal in a second frequency band; a first analog to digital converter (ADC) operating at a first sampling frequency and configured to convert the first filtered signal to a first digital signal; and a second ADC operating at a second sampling frequency and configured to convert the second filtered signal to a second digital signal, wherein the first frequency band is selected to avoid a first Nyquist boundary zone associated with the first sampling frequency and the second frequency band is selected to avoid a second Nyquist boundary zone associated with the second sampling frequency.

In some cases, the system further comprises an input switch configured to selectively couple the received RF signal to the first bandpass filter or the second bandpass filter. In some cases, the system further comprises an output switch configured to selectively couple either the first digital signal or the second digital signal to an output port of the sampling system. In some cases, the first sampling frequency is in the range of 3790 megahertz (MHz) to 3810 MHz and the second sampling frequency is in the range of 4990 MHz to 5010 MHz. In some cases, the first frequency band and the second frequency band each extend over a sub-octave frequency range and the first frequency band partially overlaps the second frequency band. In some cases, the first Nyquist boundary zone includes: a first sub-zone centered at one half of the first sampling frequency and extending over a guard band range of the first bandpass filter; and a second sub-zone centered at the first sampling frequency and extending over the guard band range of the first bandpass filter. In some cases, the second Nyquist boundary zone includes: a first sub-zone centered at one half of the second sampling frequency and extending over a guard band range of the second bandpass filter; and a second sub-zone centered at the second sampling frequency and extending over the guard band range of the second bandpass filter.

Another example embodiment of the present disclosure provides a receiver comprising: an antenna to receive a radio frequency (RF) signal; and a sampling system comprising a plurality of channels, each channel including a first bandpass filter configured to filter the RF signal to generate a first filtered signal in a first frequency band, a second bandpass filter configured to filter the RF signal to generate a second filtered signal in a second frequency band, a first analog to digital converter (ADC) operating at a first sampling frequency and configured to convert the first filtered signal to a first digital signal, and a second ADC operating at a second sampling frequency and configured to convert the second filtered signal to a second digital signal, wherein the first frequency band is selected to avoid a first Nyquist boundary zone associated with the first sampling frequency and the second frequency band is selected to avoid a second Nyquist boundary zone associated with the second sampling frequency.

In some cases, each channel includes an input switch configured to selectively couple the RF signal to the first bandpass filter or the second bandpass filter. In some cases, each channel includes an output switch configured to selectively couple either the first digital signal or the second digital signal to an output port of the channel. In some cases, the first sampling frequency is in the range of 3790 megahertz (MHz) to 3810 MHz and the second sampling frequency is in the range of 4990 MHz to 5010 MHz. In some cases, the first frequency band and the second frequency band each extend over a sub-octave frequency range and the first frequency band partially overlaps the second frequency band. In some cases, the first Nyquist boundary zone includes: a first sub-zone centered at one half of the first sampling frequency and extending over a guard band range of the first bandpass filter; and a second sub-zone centered at the first sampling frequency and extending over the guard band range of the first bandpass filter. In some cases, the second Nyquist boundary zone includes: a first sub-zone centered at one half of the second sampling frequency and extending over a guard band range of the second bandpass filter; and a second sub-zone centered at the second sampling frequency and extending over the guard band range of the second bandpass filter. In some cases, the plurality of channels is four channels and the receiver is sized to a 3U VPX form factor.

Another example embodiment of the present disclosure provides a method for analog signal sampling, the method comprising: filtering, by a first bandpass filter, a received radio frequency (RF) signal to generate a first filtered signal in a first frequency band; filtering, by a second bandpass filter, the received RF signal to generate a second filtered signal in a second frequency band; converting, by a first analog to digital converter (ADC), the first filtered signal to a first digital signal, the first ADC operating at a first sampling frequency; and converting, by a second ADC, the second filtered signal to a second digital signal, the second ADC operating at a second sampling frequency, wherein the first frequency band is selected to avoid a first Nyquist boundary zone associated with the first sampling frequency and the second frequency band is selected to avoid a second Nyquist boundary zone associated with the second sampling frequency.

In some cases, the first sampling frequency is in the range of 3790 megahertz (MHz) to 3810 MHz and the second sampling frequency is in the range of 4990 MHz to 5010 MHz. In some cases, the first frequency band and the second frequency band each extend over a sub-octave frequency range and the first frequency band partially overlaps the second frequency band. In some cases, the first Nyquist boundary zone includes: a first sub-zone centered at one half of the first sampling frequency and extending over a guard band range of the first bandpass filter; and a second sub-zone centered at the first sampling frequency and extending over the guard band range of the first bandpass filter. In some cases, the second Nyquist boundary zone includes: a first sub-zone centered at one half of the second sampling frequency and extending over a guard band range of the second bandpass filter; and a second sub-zone centered at the second sampling frequency and extending over the guard band range of the second bandpass filter.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

1. A sampling system comprising:
a first bandpass filter configured to filter a received radio frequency (RF) signal to generate a first filtered signal in a first frequency band;
a second bandpass filter configured to filter the received RF signal to generate a second filtered signal in a second frequency band;
a first analog to digital converter (ADC) operating at a first sampling frequency and configured to convert the first filtered signal to a first digital signal; and
a second ADC operating at a second sampling frequency and configured to convert the second filtered signal to a second digital signal, wherein the first frequency band is selected to avoid a first Nyquist boundary zone associated with the first sampling frequency and the second frequency band is selected to avoid a second Nyquist boundary zone associated with the second sampling frequency.

2. The system of claim 1, further comprising an input switch configured to selectively couple the received RF signal to the first bandpass filter or the second bandpass filter.

3. The system of claim 1, further comprising an output switch configured to selectively couple either the first digital signal or the second digital signal to an output port of the sampling system.

4. The system of claim 1, wherein the first sampling frequency is in the range of 3790 megahertz (MHz) to 3810 MHz and the second sampling frequency is in the range of 4990 MHz to 5010 MHz.

5. The system of claim 1, wherein the first frequency band and the second frequency band each extend over a sub-octave frequency range and the first frequency band partially overlaps the second frequency band.

6. The system of claim 1, wherein the first Nyquist boundary zone includes: a first sub-zone centered at one half of the first sampling frequency and extending over a guard band range of the first bandpass filter; and a second sub-zone centered at the first sampling frequency and extending over the guard band range of the first bandpass filter.

7. The system of claim 1, wherein the second Nyquist boundary zone includes: a first sub-zone centered at one half of the second sampling frequency and extending over a guard band range of the second bandpass filter; and a second sub-zone centered at the second sampling frequency and extending over the guard band range of the second bandpass filter.

8. A receiver comprising:
an antenna to receive a radio frequency (RF) signal; and
a sampling system comprising a plurality of channels, each channel including
a first bandpass filter configured to filter the RF signal to generate a first filtered signal in a first frequency band,
a second bandpass filter configured to filter the RF signal to generate a second filtered signal in a second frequency band,
a first analog to digital converter (ADC) operating at a first sampling frequency and configured to convert the first filtered signal to a first digital signal, and
a second ADC operating at a second sampling frequency and configured to convert the second filtered signal to a second digital signal, wherein the first frequency band is selected to avoid a first Nyquist boundary zone associated with the first sampling frequency and the second frequency band is selected to avoid a second Nyquist boundary zone associated with the second sampling frequency.

9. The receiver of claim 8, wherein each channel includes an input switch configured to selectively couple the RF signal to the first bandpass filter or the second bandpass filter.

10. The receiver of claim 8, wherein each channel includes an output switch configured to selectively couple either the first digital signal or the second digital signal to an output port of the channel.

11. The receiver of claim 8, wherein the first sampling frequency is in the range of 3790 megahertz (MHz) to 3810 MHz and the second sampling frequency is in the range of 4990 MHz to 5010 MHz.

12. The receiver of claim 8, wherein the first frequency band and the second frequency band each extend over a sub-octave frequency range and the first frequency band partially overlaps the second frequency band.

13. The receiver of claim 8, wherein the first Nyquist boundary zone includes: a first sub-zone centered at one half of the first sampling frequency and extending over a guard band range of the first bandpass filter; and a second sub-zone centered at the first sampling frequency and extending over the guard band range of the first bandpass filter.

14. The receiver of claim 8, wherein the second Nyquist boundary zone includes: a first sub-zone centered at one half of the second sampling frequency and extending over a guard band range of the second bandpass filter; and a second sub-zone centered at the second sampling frequency and extending over the guard band range of the second bandpass filter.

15. The receiver of claim 8, wherein the plurality of channels is four channels and the receiver is sized to a 3U VPX form factor.

16. A method for analog signal sampling, the method comprising:
filtering, by a first bandpass filter, a received radio frequency (RF) signal to generate a first filtered signal in a first frequency band;
filtering, by a second bandpass filter, the received RF signal to generate a second filtered signal in a second frequency band;
converting, by a first analog to digital converter (ADC), the first filtered signal to a first digital signal, the first ADC operating at a first sampling frequency; and
converting, by a second ADC, the second filtered signal to a second digital signal, the second ADC operating at a second sampling frequency, wherein the first frequency band is selected to avoid a first Nyquist boundary zone associated with the first sampling frequency and the second frequency band is selected to avoid a second Nyquist boundary zone associated with the second sampling frequency.

17. The method of claim 16, wherein the first sampling frequency is in the range of 3790 megahertz (MHz) to 3810 MHz and the second sampling frequency is in the range of 4990 MHz to 5010 MHz.

18. The method of claim 16, wherein the first frequency band and the second frequency band each extend over a sub-octave frequency range and the first frequency band partially overlaps the second frequency band.

19. The method of claim 16, wherein the first Nyquist boundary zone includes: a first sub-zone centered at one half of the first sampling frequency and extending over a guard band range of the first bandpass filter; and a second sub-zone centered at the first sampling frequency and extending over the guard band range of the first bandpass filter.

20. The method of claim 16, wherein the second Nyquist boundary zone includes: a first sub-zone centered at one half of the second sampling frequency and extending over a guard band range of the second bandpass filter; and a second sub-zone centered at the second sampling frequency and extending over the guard band range of the second bandpass filter.
